(19) United States
(12) Patent Application Publication
(10) Pub. No.: US 2008/0073067 A1
(43) Pub. Date: Mar. 27, 2008

(54) Noise elimination apparatus for radiator

(75) Inventor: Kun-Hang Lo, Hsichih (TW)

Correspondence Address: BRUCE H. TROXELL, SUITE 1404, 5205 LEESBURG PIKE, FALLS CHURCH, VA, 22041, US

(73) Assignee: AOPEN INC.

(21) Appl. No.: 11/802,239

(22) Filed: May 21, 2007

(30) Foreign Application Priority Data
Sep. 8, 2006 (TW) 095214063

(51) Int. Cl. H05K 7/20

(52) U.S. Cl. 165/135

(57) ABSTRACT

A noise elimination apparatus for a radiator allows an elastic cushion to shield a plurality of screw holes on a upper cover to enable air flow driven by a fan not to be expelled out through the screw holes; an elastic blocking plate is combined with the radiator at an inner side of an exhaust thereof; the blocking plate shields a gap between a bottom portion of an opening at an inner side of a scooper to cause air flow expelled via the exhaust of the radiator not to be expelled through the gap mentioned above. Whereby, wind shear sound and annoying high frequency noise generated when the fan is working can be reduced.

### BACKGROUND OF THE INVENTION

1. Field of the Invention

The present invention relates to a radiator of an electronic device, and more particularly to a noise elimination apparatus for a radiator for a central processing unit (CPU).

2. Description of Related Art

A radiator for a general CPU comprises a fan. When the fan is operating, it generates wind shear and annoying high frequency noise. However, the fan is still used for processing cooling under cost consideration because a new technology and new material are not broken through broadly; a noise problem still exists.

There are many technologies about decreasing noise generated when the fan is working, for example, a radiator module with a noise restriction structure disclosed in Taiwan patent publication No. 200604445 allows noise generated when a fan is working to be shielded in a guiding duct to decrease noise volume when the fan is working. Furthermore, a cooling fan structure of a computer mainframe disclosed in Taiwan Patent No. I249,664 is constituted to allow a fan main body to be fixed on a housing of the computer mainframe without needing screws and the shock absorption and the noise decreasing effects can be attained concurrently.

Please refer to FIGS. 1, 2 and 3. A conventional CPU radiator 10 comprises a bottom plate 11 and an upper cover 12, in which components such as cooling fins 13 and a fan 14 are combined between the bottom plate 11 and the upper cover 12. The radiator 10 has an exhaust 15 used for allowing air flow driven by the fan 14 to flow through the cooling fins 13 and be expelled via it. The upper cover 12 is provided with a plurality of screw holes 121 used for allowing a plurality of screws 16 to pass through them from the upper side of the upper cover 12 to enable the bottom plate 11 to be fixed onto a frame body 31 of an electronic device as FIGS. 2 and 3 show. An air ducting frame body 20 is provided with a cover body 21 and air scooper 22 connected to each other, in which the cover body 21 is covered on the upper end of the upper cover 12 and the inner side end of the air scooper 22 is positioned at the outer side of the exhaust 15. The outer side end of the air scooper 22 is positioned at the inner side end of a vent 321 of the housing 32 of the electronic device. Whereby, hot air flow expelled from the radiator 10 is guided through the air scooper 22 and expelled out of the housing 31 of the electronic device via the vent 321.

The conventional combination structure of the radiator 10 and the air ducting frame body 20 has the following deficiencies:
1. please refer to FIG. 1 again. A part of the air flow driven by the fan 14 might be expelled via the screw holes 121 because of the dispositions of the screw holes 121 on the upper cover 12 to generate wind shear sound and annoying high frequency noise. Besides, the air flow driven by the fan 14 cannot be guided to the cooling fins 13 completely; this also causes the energy waste.
2. please refer to FIG. 2 again. A gap exists between the bottom of an opening at the inner side end of the air scooper 22 and the bottom plate 11 and a gap also exists between the flank side of the opening at the inner side end of the air scooper 22 and one flank side 122 of the upper cover 12 as FIG. 2 shows because the height and the width of the exhaust 15 of the radiator 10 respectively are larger than the height and the width of the opening at the inner side end of the air scooper 22, it causes a part of the air flow expelled via the exhaust 14 of the radiator 10 to be expelled through the gaps mentioned above such that wind shear sound and annoying high frequency sound are yielded. Besides, the expelled hot wind is caused to flow back to the inner part of the electronic device so that the cooling efficiency of the radiator 10 is decreased.

### SUMMARY OF THE INVENTION

For decreasing noise generated when a conventional CPU radiator is operating and increasing the cooling efficiency of the radiator, the present invention is proposed.

The main object of the present invention is to provide a noise elimination apparatus for a radiator, capable of decreasing noise generated from the radiator.

Another object of the present invention is to provide a noise elimination apparatus for a radiator, capable of further increasing the cooling efficiency of the radiator.

A noise elimination apparatus for a radiator is used for decreasing noise generated when the radiator is operating and increasing the cooling efficiency, comprises:

a radiator, comprising a bottom plate and a upper cover; cooling fins and a fan are combined between the bottom plate and the upper cover; the radiator has an exhaust used for allowing air flow driven by the fan to flow through the cooling fins and be expelled via the exhaust; the upper cover has a plurality of screw holes used for allowing a plurality of screws to be passed through the screw holes form the upper side of the upper cover to enable the bottom plate to be combined with a frame body of an electronic device;

a wind guiding frame body, having a cover body and an air scooper connected to each other;

a cushion, corresponding to the screw holes on the upper cover;

Wherein, the cover body is covered on a upper end of the upper cover, an inner side end of the air scooper is disposed at an outer side of the exhaust; the cushion shields the screw holes on the upper cover so as to allow the air flow driven by the fan not to be expelled through the screw holes to improve the noise generated when the radiator is operating and increase the cooling efficiency of the radiator.

### BRIEF DESCRIPTION OF THE DRAWINGS

The present invention can be more fully understood by reference to the following description and accompanying drawings, in which:

FIG. 1 is a perspective view, showing a conventional radiator and scooper frame body separated from each other;

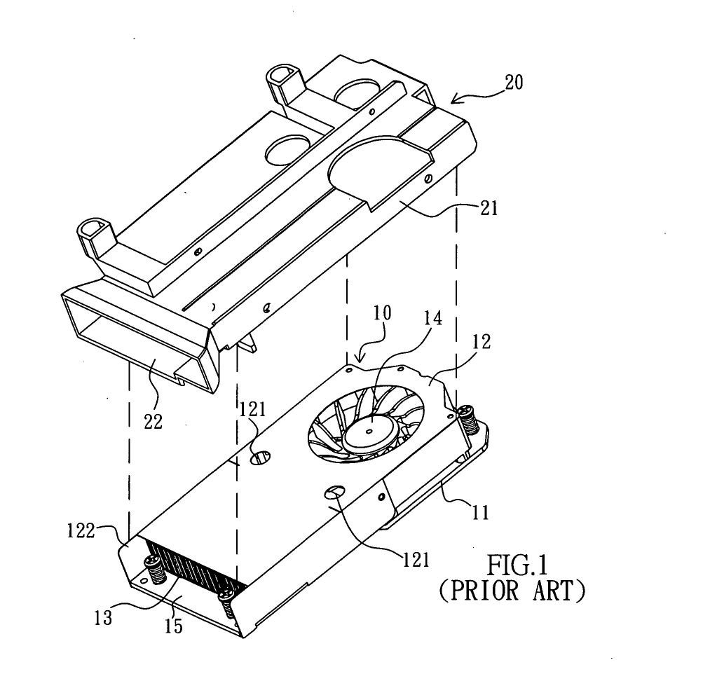

FIG. 2 is a perspective bottom view, showing a combination article of a conventional radiator and scooper frame body;

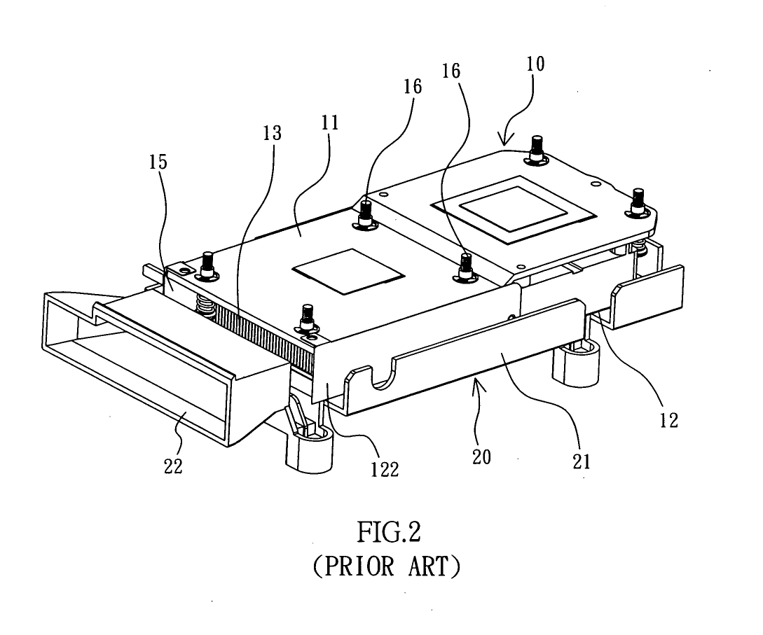

FIG. 3 is a perspective view, showing an electronic device combined with a conventional radiator and scooper frame body;

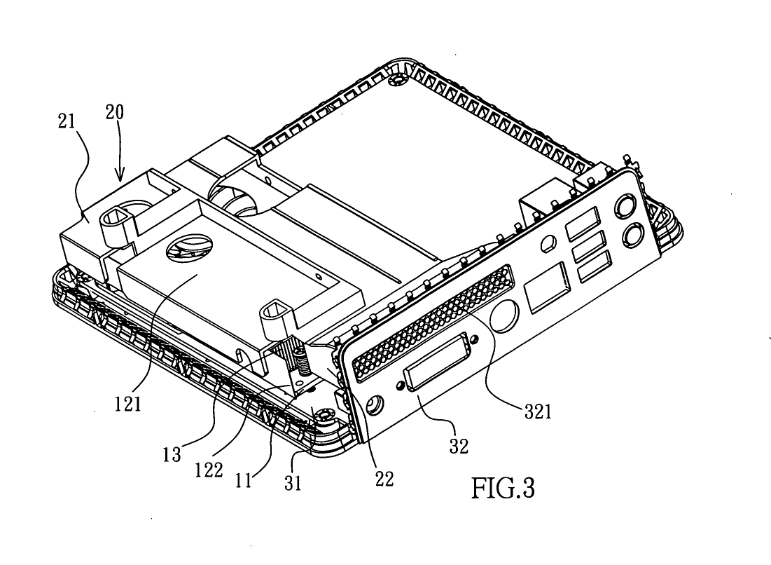

FIG. 4 is a perspective view, showing a radiator and scooper frame body separated from each other according to the present invention;

FIG. 5 is a perspective bottom view, showing a combination article of a radiator and scooper frame body according to the present invention; and

FIG. 6 is a perspective view, showing an electronic device combined with a radiator and scooper frame body; according to the present invention.

### DETAILED DESCRIPTION OF THE PREFERRED EMBODIMENTS

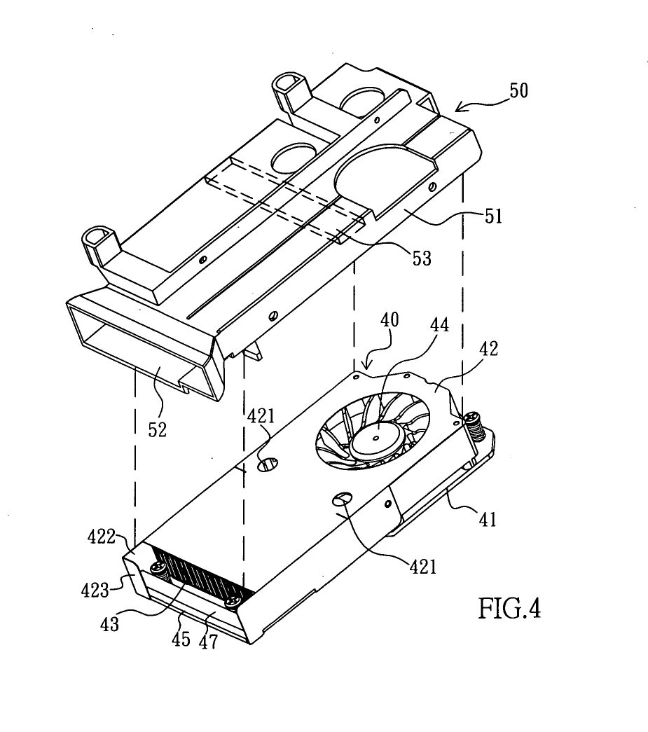

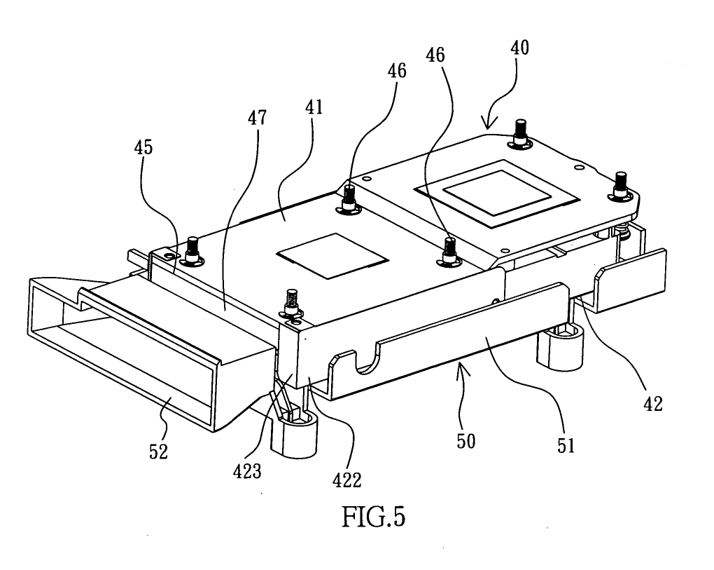

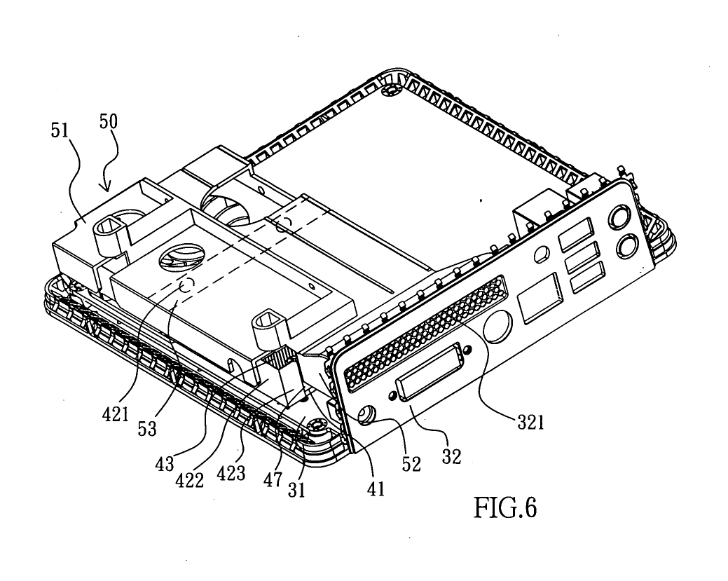

Please refer to FIGS. 4, 5 and 6. A noise elimination apparatus for a radiator according to the present invention is used for decreasing noise value generated and increasing the cooling efficiency when the radiator is operating, it comprises a radiator 40 and a scooper frame body 50. The radiator 40 comprises a bottom plate 41 and an upper cover 42. Components such as cooling fins 43 and a fan 44 are combined between the bottom plate 41 and the upper cover 42. The radiator 40 has an exhaust 45 for allowing the fan 44 to drive air flow to flow through the cooling fins 43 and be expelled out via exhaust 45. The upper cover 42 has a plurality of screw holes 421 for allowing a plurality of screws 46 to be passed through the screw holes 421 from the upper side of the upper cover 42 to enable the bottom plate 41 to be combined with an electronic device on a frame body 31 thereof as FIGS. 5 and 6 show. Furthermore, the scooper frame body 50 has a cover body 51 and a scooper 52 connected to each other.

The cover body 51 is covered on the upper end of the upper cover 42. The inner side end of the scooper 52 is positioned at the outer side of the exhaust 45 and the outer side end of the scooper 52 is positioned at the inner side of a vent 321 of a housing 32 of the electronic device to allow hot air flow expelled from the radiator to be expelled out of the housing 32 of the electronic device via the vent 321 by means of the guidance of the scooper 52 as FIGS. 5 and 6 show.

One of the characteristics of the present invention is in that an elastic cushion 53 is allowed to shield the screw holes 421 of the upper cover 42 after the bottom plate 41 is combined with the electronic device on a frame body 31 thereof or the inner side of the cover body 21 is allowed to combined with the cushion 53 as FIG. 4 shows. The cushion 53 shields the screw holes 421 after the cover body 51 is combined with the upper cover 42 to enable the air flow driven by the fan 44 not to be expelled out via the screw holes 421 so that the wind shear sound and the annoying high frequency noise are not yielded and the air flow driven by the fan 44 is completely guided to the cooling fins 43 without causing the energy waste as FIG. 6 shows.

Another characteristic of the present invention is in that an elastic blocking plate 47 is combined with the radiator 40 at the inner side of the exhaust 45 as FIG. 4 shows. The blocking plate 47 shields a gap between the bottom of an opening at the inner side end of the scooper 52 and the bottom plate 41 as FIG. 5 shows. Furthermore, a bending tab 423 is disposed on an end portion of one flank side 422 of the upper cover 42 as FIG. 4 shows. The tab 423 shields a gap between the flank side of the opening at the inner side end of the scooper 52 and one flank side 422 of the upper cover 42 as FIG. 5 shows; this allows the air flow expelled via the exhaust 45 of the radiator 40 not to be expelled through two gaps mentioned above to generate the wind shear sound and the annoying high frequency noise. Besides, the expelled hot wind is not allowed to flow back the inside part of the electronic device so as to increasing the cooling efficiency of the radiator 40.

The cushion 53 and the blocking plate 47 according to the present invention can respectively be made from an elastic material such as foam, which is low cost and easy manufacturing. The present invention uses the simple type cushion 53 and blocking plate 47 to match up with the complex components of the radiator 40 and the scooper 52 and hot wind can then be expelled quickly out of the housing of the electronic device via radiator 40 and the scooper 52.

A noise elimination apparatus for a radiator according to the present invention can improve the noise value generated when a conventional radiator is working increase the cooling efficiency of the conventional radiator obviously.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A noise elimination apparatus for a radiator, used for decreasing noise value generated when said radiator is working and increasing the cooling efficiency, comprising:
said radiator, comprising a bottom and a upper cover, cooling fins and a fan being combined between said bottom plate and said upper cover, said radiator having an exhaust used for allowing air flow driven by said fan to flow through said cooling fins and be expelled via said exhaust, said upper cover having a plurality of screw holes used for allowing a plurality screws to be passed through said screw holes from the upper side of said upper cover to enable said bottom plate to be combined with a frame body of an electronic device;
a scooper frame body, having a cover body and a scooper connected to each other;
a cushion, corresponding to a plurality of screw holes of said upper cover;
wherein said cover body is covered on a upper end of said upper cover, an inner side end of said scooper is position at an outer side of said exhaust, said cushion shields said screw holes of said upper cover so as to allow said air flow driven by said fan not to be expelled through said screw holes.

2. The noise elimination apparatus according to claim 1, wherein an inner side of said cover body is combined with said cushion.

3. The noise elimination apparatus according to claim 2, wherein said cushion is elastic.

4. The noise elimination apparatus according to claim 3, wherein said cushion is made from a foam material.

5. The noise elimination apparatus according to claim 1, wherein a blocking plate is combined with said radiator at an inner side of said exhaust; said blocking plate shields a gap between a bottom portion of an opening at an inner side end of said scooper and said bottom plate so as to allow said air flow driven by said fan not to be expelled through said gap.

6. The noise elimination apparatus according to claim 5, wherein said blocking plate is elastic.

7. The noise elimination apparatus according to claim 6, wherein said blocking plate is made from a foam material.

8. The noise elimination apparatus according to claim 5, wherein an inner side of said cover body is combined with said cushion.

9. The noise elimination apparatus according to claim 8, wherein said cushion is elastic.

10. The noise elimination apparatus according to claim 9, wherein said cushion is made from a foam material.

11. The noise elimination apparatus according to claim 8, wherein said blocking plate is elastic.

12. The noise elimination apparatus according to claim 9, wherein said blocking plate is made from a foam material.

13. The noise elimination apparatus according to claim 5, further comprising a bending tab; said bending tab is disposed on an end portion of a flank side of the upper cover; said bending tab shields a gap between the flank side of the opening at the inner side end of the scooper and the flank side of the upper cover.

14. The noise elimination apparatus according to claim 8, further comprising a bending tab; said bending tab is disposed on an end portion of a flank side of the upper cover; said bending tab shields a gap between the flank side of the opening at the inner side end of the scooper and the flank side of the upper cover.
